(19) United States
(12) Patent Application Publication
(10) Pub. No.: US 2025/0316578 A1
(43) Pub. Date: Oct. 9, 2025

(54) INDUCTOR-CAPACITOR CIRCUIT STRUCTURE AT HYBRID BONDING INTERFACE

(71) Applicant: International Business Machines Corporation, Armonk, NY (US)

(72) Inventors: Kishan Jayanand, COHOES, NY (US); Nicholas Alexander POLOMOFF, Hopewell Junction, NY (US); Viswas Purohit, East Amherst, NY (US); Nicholas Latham, Albany, NY (US); Mukta Ghate Farooq, Hopewell Junction, NY (US); Ashim Dutta, Clifton Park, NY (US); Chih-Chao Yang, Glenmont, NY (US)

(21) Appl. No.: 18/628,008

(22) Filed: Apr. 5, 2024

(51) Int. Cl. H01L 23/522; H01L 21/02; H01L 21/321; H01L 23/00

(52) U.S. Cl. CPC H01L 23/5223; H01L 21/0228; H01L 21/3212; H01L 23/5227; H01L 24/81; H10D 1/692; H01L 2224/814; H01L 2224/81801

(57) ABSTRACT

A structure is provided that includes an inductor-capacitor (L-C) circuit that is connected at a hybrid bonding interface. Notably, the L-C circuit includes a top portion and a bottom portion that are connected together at the hybrid bonding interface. The L-C circuit can be used as a monitoring device that can detect and transmit data related to at least one of temperature, strain and humidity at the hybrid bonding interface.

### BACKGROUND

The present application relates to semiconductor technology, and more particularly to a structure that includes an inductor-capacitor (L-C) circuit that is connected at a hybrid bonding interface.

An L-C circuit, consisting of an inductor (L) and a capacitor (C) connected together, can oscillate, i.e., it can exchange energy between magnetic fields in the inductor and electric fields in the capacitor. L-C circuits have frequency variability and sensing capabilities. The frequency variability, i.e., shifts, are caused by change in capacitance in response to alterations in the environment. Deviations from resonant frequency values can be decoded as indicative signal, providing insights into parameter changes or potential anomalies. Frequency variations facilitate early detection of potential issues or material degradation allowing for preventative actions. Continuous frequency monitoring and data interpretation can enhance the reliability and operational lifetime of semiconductor devices by enabling timely interventions. In essence, by observing shifts in the resonant frequency of the L-C circuit, the system can transmit vital data about physical parameters and potential failure modes, ensuring stable and sustained operation of the semiconductor device.

### SUMMARY

A structure is provided that includes an inductor-capacitor (L-C) circuit that is located at a hybrid bonding interface. Notably, the L-C circuit includes a top portion and a bottom portion that are connected together at the hybrid bonding interface. The L-C circuit can be used as a monitoring device that can detect and transmit data related to at least one of temperature, strain and humidity at the hybrid bonding interface.

In one aspect of the present application, a structure is provided that includes a bottom bonding dielectric layer located on a surface of a bottom semiconductor die. In the present application, the bottom bonding dielectric layer and the bottom semiconductor die have a bottom portion of an L-C circuit present therein. The structure further includes a top bonding dielectric layer located on a surface of a top semiconductor die and in contact with the bottom bonding dielectric layer. In the present application, the top bonding dielectric layer and the top semiconductor die have a top portion of the L-C circuit present therein. In the structure, the top portion of the L-C circuit is connected to the bottom portion of the L-C circuit at a hybrid bonding interface.

In another aspect of the present application, a structure is provided that includes a bottom bonding dielectric layer located on a surface of a bottom semiconductor die. In this structure, the bottom bonding dielectric layer has a bottom capacitor portion present therein and the bottom semiconductor die has a bottom inductor present therein. This structure further includes a top bonding dielectric layer located on a surface of a top semiconductor die and in contact with the bottom bonding dielectric layer. In this structure, the top bonding dielectric layer has a top capacitor portion present therein, and the top semiconductor die has a top inductor present therein. This structure even further includes a hybrid bonding interface located between the bottom bonding dielectric layer and the top bonding dielectric layer at which the top inductor is connected to the bottom inductor, and the top capacitor portion is connected to the bottom capacitor portion.

### BRIEF DESCRIPTION OF THE DRAWINGS

FIG. 1A is a cross sectional view of a first exemplary semiconductor die that can be employed in the present application, the first exemplary semiconductor die including a first combined front-end-of-the-line (FEOL)/middle-of-the-line (MOL) structure and a first back-end-of-the-line (BEOL) structure.

FIG. 1B is a cross sectional view of a second exemplary semiconductor die that can be employed in the present application, the second exemplary semiconductor die including a second combined FEOL/MOL structure and a second BEOL structure.

FIG. 2A is a cross sectional view of the first exemplary semiconductor die shown in FIG. 1A after forming a first via opening and a first inductor opening in an uppermost first BEOL interconnect dielectric layer of the first BEOL structure, and filling the first via opening and the first inductor opening with an electrically conductive metal or electrically conductive metal alloy.

FIG. 2B is a cross sectional view of the second exemplary semiconductor die shown in FIG. 1B after forming a second via opening and a second inductor opening in an uppermost second BEOL interconnect dielectric layer of the second BEOL structure, and filling the second via opening and the second inductor opening with an electrically conductive metal or electrically conductive metal alloy.

FIG. 3A is a cross sectional view of the first exemplary semiconductor die shown in FIG. 2A after forming a first bonding dielectric layer on the uppermost first BEOL interconnect dielectric layer of the first BEOL structure and forming first capacitor dielectric regions in the first bonding dielectric layer.

FIG. 3B is a cross sectional view of the second exemplary semiconductor die shown in FIG. 2B after forming a second bonding dielectric layer on the uppermost second BEOL interconnect dielectric layer of the second BEOL structure and forming second capacitor dielectric regions in the second bonding dielectric layer.

FIG. 4A is a cross sectional view of the first exemplary semiconductor die shown in FIG. 3A after forming spaced apart first capacitor plates in one of the first capacitor dielectric regions.

FIG. 4B is a cross sectional view of the second exemplary semiconductor die shown in FIG. 3B after forming spaced apart second capacitor plates in one of the second capacitor dielectric regions.

FIG. 5 is a cross sectional view of both the first and second exemplary semiconductor dies after flipping the first exemplary semiconductor die shown in FIG. 4A and aligning the flipped first exemplary semiconductor die over the second exemplary semiconductor die shown in FIG. 4B.

FIG. 6 is a cross sectional view of the flipped and aligned first exemplary semiconductor die and second exemplary semiconductor die shown in FIG. 5 after bringing the two exemplary semiconductor dies into intimate contact with each other and performing a bonding process to provide a structure having a hybrid bonded L-C circuit in accordance with the present application.

FIG. 7 is a cross sectional view of the structure shown in FIG. 8 after further device processing.

FIG. 8 is a three dimensional (3D) illustration of the hybrid bonded L-C circuit of the present application.

FIG. 9A is a top down view illustrating the hybrid bonded L-C circuit of the present application.

FIG. 9B is a cross sectional view of the hybrid bonded L-C circuit of the present application.

FIGS. 10A-10E shows various inductor shapes that can be employed in the hybrid bonded L-C circuit of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Throughout the present application, the term “inductor” denotes a passive electrical component that consists of electrically conductive wires. An inductor is designed to take advantage of the relationship between magnetism and electricity. Notably, and when current flows through the inductor, a magnetic flux develops around it. This magnetic flux is proportional to the current flowing through it. The inductor opposes changes in the current flow (both in magnitude and direction), and it resists rapid changes in the current due to the build-up of self-induced energy within its magnetic field. In other words, an inductor stores energy in its magnetic field when current flows through it.

Throughout the present application, the term “capacitor” denotes an electric component that stores electrical energy by accumulating electric charges on two closely spaced apart electrically conductive plates that are insulated from each other by a capacitor dielectric material.

Throughout the present application, the term “inductor-capacitor circuit or L-C circuit” denotes an electronic device that includes an inductor (L) and a capacitor (C) connected together. In the present application, the L-C circuit will include two inductors and a single capacitor that is composed of two separate capacitor portions (i.e., halves) that are bonded together (i.e., connected) at a hybrid bonding interface. The L-C circuit can oscillate, i.e., it can exchange energy between magnetic fields in the inductors and electric fields in the capacitor. L-C circuits have frequency variability and sensing capabilities. In the present application, the L-C circuit includes a top portion of the L-C circuit that is connected to a bottom portion of the L-C circuit at a hybrid bonding interface. The L-C circuit of the present application is thus a hybrid bonded L-C circuit that includes a hybrid bonding interface at which a top capacitor portion is connected to a bottom capacitor portion, and a top inductor is connected to a bottom inductor. In the present application, the top inductor is connected to signal in/out.

Throughout the present application, the term “semiconductor die” denotes a block of a semiconducting material on which a given functional circuit is fabricated. The semiconductor material and the circuit are located in the front-end-of-the-line (FEOL) level. The semiconducting material can include, for example, silicon (Si), a silicon germanium (SiGe) alloy, a silicon germanium carbide (SiGeC) alloy, germanium (Ge), III/V compound semiconductors or II/VI compound semiconductors. Typically, integrated circuits (ICs) are produced in large patches on a single semiconductor substrate (or wafer) through various processes that are well-known to those skilled in the art of IC fabrication. The substrate (or wafer) is then cut (i.e., diced) into many pieces, each containing a copy of the IC. Each of these pieces is called a semiconductor die (or die). The semiconductor die can also include a middle-of-the-line (MOL) level that includes MOL contact structures embedded in an interlayer dielectric (ILD) layer. The MOL level can be formed utilizing processes well-known in the art. The semiconductor die can also include a BEOL structure located above the MOL level. The MOL level and BEOL structure are formed prior to the cutting process.

Throughout the present application, the term “integrated circuit (or IC)” denotes an electronic device made up of multiple interconnect electronic components such, as, for example, transistors, resistors and capacitors. These components can be formed onto a semiconductor substrate utilizing any FEOL device process that is well-known to those skilled in the art of semiconductor device manufacturing.

Throughout the present application, the term “BEOL structure” denotes a structure including metal wires (i.e., metal lines and/or metal vias) embedded in multiple interconnect dielectric layers. Some of the metal wires of the BEOL structure can be used to interconnect with the ICs that are present at the FEOL. The metal wires (i.e., metal lines and/or metal vias) are composed of an electrically conductive metal or an electrically conductive metal alloy. Illustrative examples of electrically conductive metals that can be used in forming the metal wires include, but are not limited to, Cu, Cu, Al, Co, Ru, Mo, Os, Ir, or Rh. An illustrative electrically conductive alloy that can be used in forming the metal wires includes, but is not limited to, a Cu—Al alloy. The interconnect dielectric layers of the BEOL structure (as well as the ILD layer mentioned above for the MOL level) include a dielectric material such as, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0 (all dielectric constants mentioned herein are relative to a vacuum unless otherwise noted). The BEOL structure can be formed utilizing well-known BEOL processes including, for example, a damascene process or a subtractive etching process.

Throughout the present application, the term “hybrid bonding” denotes dielectric-to-dielectric bonding and metal-to-metal bonding such that a hybrid bonding interface is formed between the bonded dielectric materials and the bonded metals. Throughout the present application, the term “hybrid bonding interface” denotes an interface containing dielectric-to-dielectric bonding and metal-to-metal bonding. In the present application, the hybrid bonding interface is the location at which a top portion of the L-C circuit (including a top capacitor portion and a top inductor) is connected to a bottom portion of the L-C circuit (including a bottom capacitor portion and a bottom inductor). It is again noted that in the present application, the L-C circuit includes two inductors (i.e., the top inductor and the bottom inductor) and a single capacitor (including the top and bottom capacitor portions that are bonded together into a single element at the hybrid bonding interface).

In the description of the processing flow to follow, the term “first capacitor portion” can be used interchangeably with the term “top capacitor portion”, the term “first inductor” can be used interchangeably with the term “top inductor”, the term “second capacitor portion” can be used interchangeably with the term “bottom capacitor portion”, and the term “second inductor” can be used interchangeably with the term “bottom inductor”.

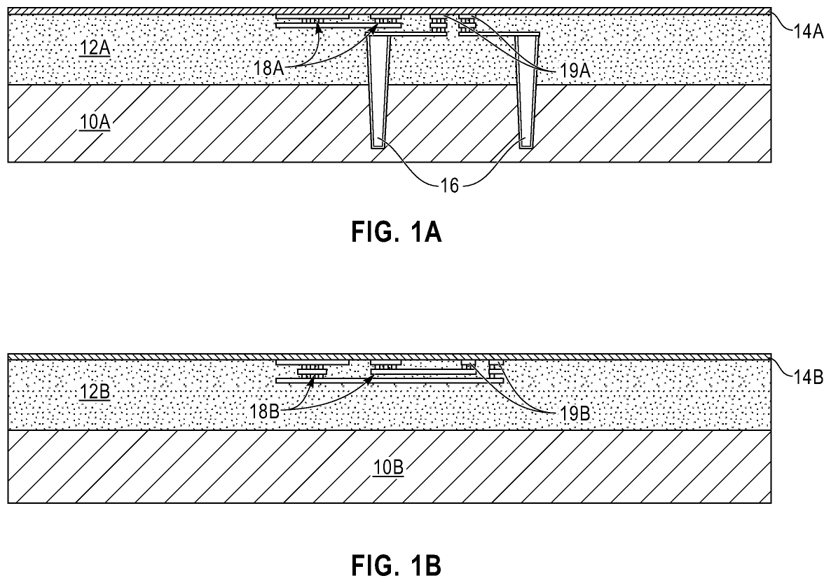

Reference is first made to FIG. 1A, which illustrates a first exemplary semiconductor die that can be employed in the present application. In the present application, the first exemplary semiconductor die includes a top portion of the L-C circuit; the top portion of the L-C circuit will include a first (i.e., top) capacitor portion and a first (i.e., top) inductor. The first semiconductor die thus can be referred to as a top semiconductor die; and all the “first” components present in the first (i.e., top) semiconductor die can be referred to as “top” components. The first exemplary semiconductor die illustrated in FIG. 1A includes a first combined FEOL/MOL structure 10A and a first BEOL structure 12A. The first combined FEOL/MOL structure 10A includes a semiconducting material, as defined above, an IC, as defined above, and MOL contact structures, as defined above. The semiconducting material, IC, and the MOL contact structures of the first combined FEOL/MOL structure 10A are not separately shown in the drawings of the present application, but each is meant to be included in the region denoted as the first combined FEOL/MOL structure 10A.

The first BEOL structure 12A, which is formed on a surface of the first combined FEOL/MOL structure 10A, includes a plurality of interconnect dielectric layers. In FIG. 1A, an uppermost first BEOL interconnect dielectric layer 14A of the first BEOL structure 12A is shown and the other interconnect dielectric layers that are beneath the uppermost first BEOL interconnect dielectric layer 14A are not independently shown in the present application, but are intended to be included within the region denoted as the first BEOL structure 12A. Within the plurality of interconnect dielectric layers that are located beneath the uppermost first BEOL interconnect dielectric layer 14A, metal wires, some of which as illustrated in FIG. 1A, are present. Notably, FIG. 1A shows a first metal wiring region 18A and a second metal wiring region 19A. In the present application, the first metal wiring region 18A will be subsequently interconnected to a first capacitor portion, while the second metal wiring region 19A will be subsequently interconnected to a first inductor. Each of the first metal wiring region 18A and the second metal wiring region 19A includes metal vias and metal lines that are composed of an electrically conductive metal or electrically conductive metal alloy, both as defined above. In the present application, the metal lines and metal vias that provide the second wiring region 19A are connected to a through via structure 16 that is present in a lower portion of the first BEOL structure 12A and partially into the first semiconductor die; typically the through via structure 16 extends into the semiconducting material that provides the first semiconductor die. The through via structure 16 is composed of an electrically conductive metal or electrically conductive metal alloy, both as defined above, and it can be formed utilizing a metallization process that is well-known to those skilled in the art.

Referring now to FIG. 1B, there is illustrated a second exemplary semiconductor die that can be employed in the present application. In the present application, the second exemplary semiconductor die includes a bottom portion of the L-C circuit; the bottom portion of the L-C circuit will include a bottom capacitor portion and a bottom inductor. The second semiconductor die thus can be referred to as a bottom semiconductor die; and all the “second” components present in the second (i.e., bottom) semiconductor die can be referred to as “bottom” components. The second exemplary semiconductor die illustrated in FIG. 1B includes a second combined FEOL/MOL structure 10B and a second BEOL structure 12B. The second combined FEOL/MOL structure 10B includes a semiconducting material, as defined above, an IC, as defined above, and MOL contact structures, as defined above. The semiconducting material, IC, and the MOL contact structures of the second combined FEOL/MOL structure 10B are not separately shown in the drawings of the present application, but each is meant to be included in the region denoted as the second combined FEOL/MOL structure 10B.

The second BEOL structure 12B, which is formed on a surface of the second combined FEOL/MOL structure 10B, includes a plurality of interconnect dielectric layers. In FIG. 1B, the uppermost second BEOL interconnect dielectric layer 14B of the second BEOL structure 12B is shown and the other interconnect dielectric layers that are beneath the uppermost second BEOL interconnect dielectric layer 14B are not illustrated in the present application, but are intended to be included within the region denoted as the second BEOL structure 12B. Within the plurality of interconnect dielectric layers that are located beneath the uppermost second BEOL interconnect dielectric layer 14B, metal wires, some of which as illustrated in FIG. 1B, are present. Notably, FIG. 1B shows a third metal wiring region 18B and a fourth metal wiring region 19B. In the present application, the third metal wiring region 18B will be subsequently interconnected to a second capacitor portion, while the fourth metal wiring region 19B will be subsequently interconnected to a second inductor. Each of the third metal wiring region 18B and the fourth metal wiring region 19B includes metal vias and metal lines that are composed of an electrically conductive metal or electrically conductive metal alloy, both as defined above. In the present application, the third metal wiring region 18B is interconnected to the fourth metal wiring region 19B as is illustrated in FIG. 1B.

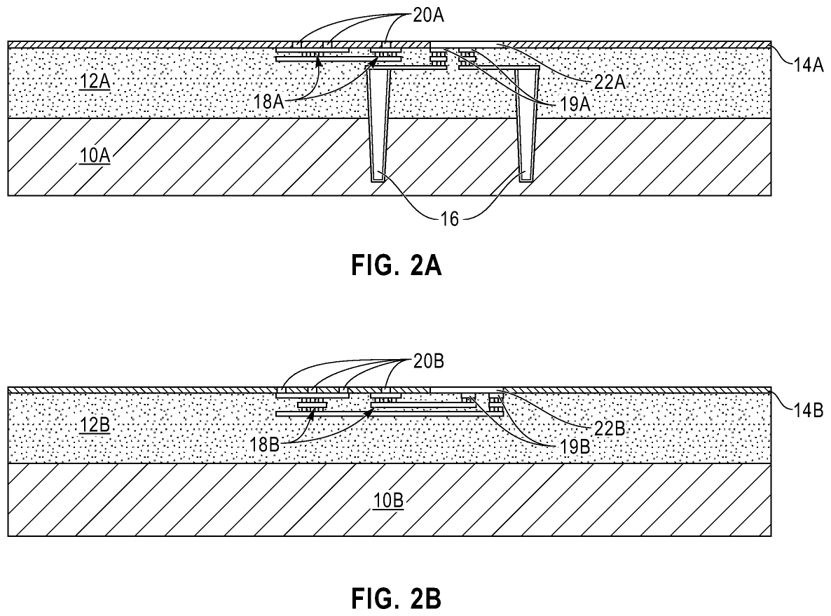

Referring now to FIG. 2A, there is illustrated the first exemplary semiconductor die shown in FIG. 1A after forming a first via opening (not specifically illustrated) and a first inductor opening (not specifically illustrated) in the uppermost first BEOL interconnect dielectric layer 14A of the first BEOL structure 12A, and filling the first via opening and the first inductor opening with an electrically conductive metal or electrically conductive metal alloy to provide a first metal via 20A and a first inductor 22A, respectively. The first via opening and the first inductor opening can be formed by lithography and etching. Lithography includes forming (by a deposition process) a photoresist material on a layer or structure that needs to be patterned, exposing the as-deposited photoresist material to a desired pattern of irradiation, and developing the exposed photoresist material. The etching can include a dry etching process or a wet etching process. Drying etching can include, for example, reactive ion etching (RIE), laser etching, or plasma etching. Wet etching includes the use of a chemical etchant. The filling of the first via opening and the first inductor opening includes depositing an electrically conductive metal or an electrically conductive metal alloy, as defined above, and then performing a planarization process such as, for example, chemical mechanical polishing (CMP), to remove any of the as-deposited electrically conductive material that is formed outside of the first via opening and the first inductor opening. The depositing of the electrically conductive material can include, but is not limited to, chemical vapor deposition (CVD), plasma enhanced chemical vapor deposition (PECVD), atomic layer deposition (ALD), sputtering or plating. As is illustrated in FIG. 2A, the first metal via 20A is in contact with the first wiring region 18A and the first inductor 22A is in contact with the second wiring region 19A. The first inductor 22A is planar.

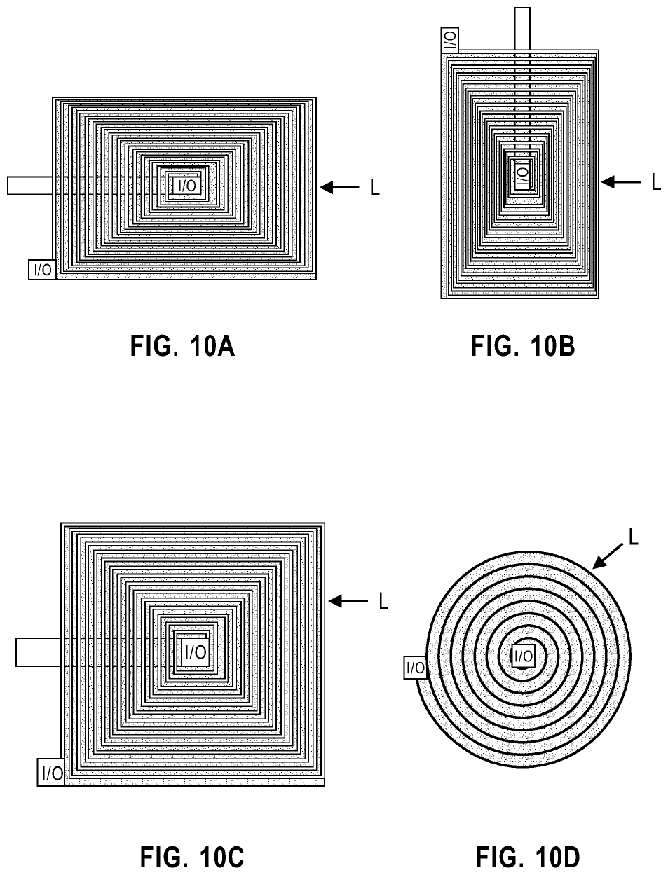

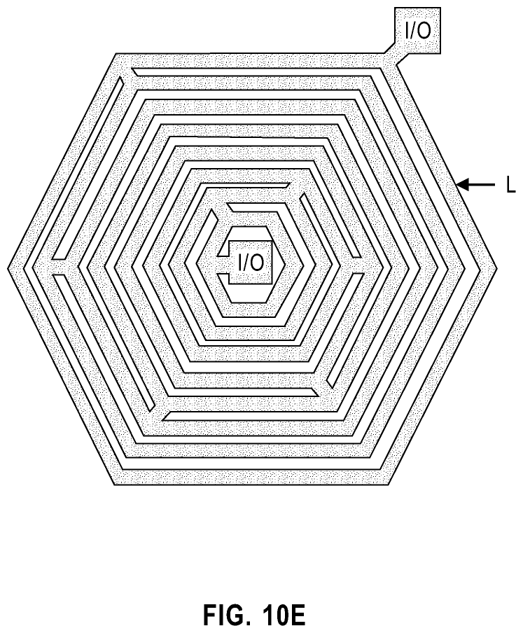

Although not apparent from the cross sectional view illustrated in FIG. 2A, the first inductor 22A can be of various shapes including rectangular, square, spiral or hexagonal. This aspect of the present application is more apparent from FIGS. 10A-10E, which will be described in greater detail herein below.

Referring now to FIG. 2B, there is illustrated the second exemplary semiconductor die shown in FIG. 1B after forming a second via opening (not specifically shown) and a second inductor opening (not specifically shown) in the uppermost second BEOL interconnect dielectric layer 14B of the second BEOL structure 12B, and filling the second via opening and the second inductor opening with an electrically conductive metal or electrically conductive metal alloy to provide a second metal via 20B and a second inductor 22B, respectively. The forming of the second via and inductor openings and the filling process are the same as those described above in forming the first metal via 20A and the first inductor 22A shown in FIG. 2A. As is illustrated in FIG. 2B, the second metal via 20B is in contact with the third wiring region 18B and the second inductor 22B is in contact with the fourth wiring region 19B. The second inductor 22B is planar.

Although not apparent from the cross sectional view illustrated in FIG. 2B, the second inductor 22B can be of various shapes including rectangular, square, spiral or hexagonal. This aspect of the present application is more apparent from FIGS. 10A-10E, which will be described in greater detail herein below. It is noted that the shape of the first inductor 22A is typically, by not necessarily always, the same as the second inductor 22B.

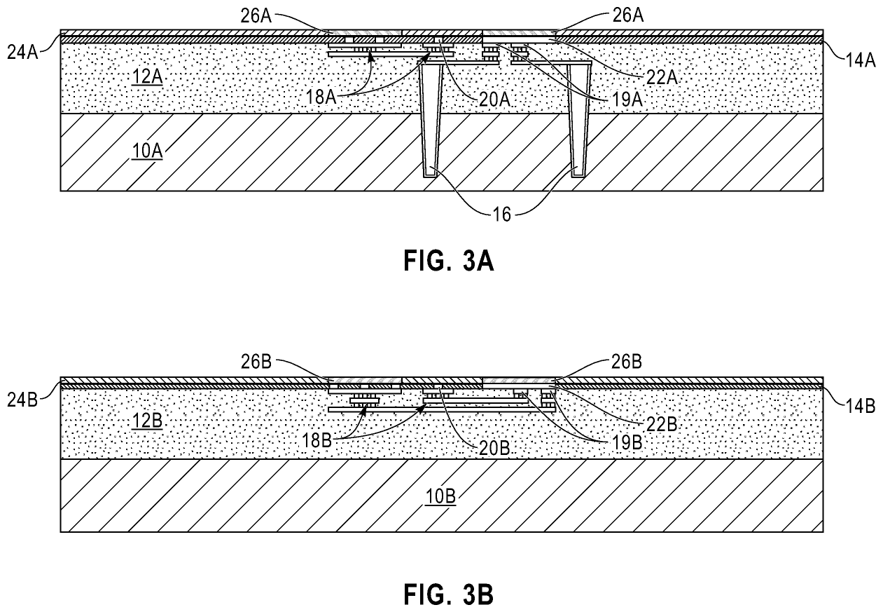

Referring now to FIG. 3A, there is illustrated the first exemplary semiconductor die shown in FIG. 2A after forming a first bonding dielectric layer 24A on the uppermost first BEOL interconnect dielectric layer 14A of the first BEOL structure 12A and forming first capacitor dielectric regions 26A in the first bonding dielectric layer 24A. Since the first bonding dielectric layer 24A is associated with the first (or top) semiconductor die, the first bonding dielectric layer 24A can also be referred to herein as a top bonding dielectric layer. The first bonding dielectric layer 24A is composed of any bonding dielectric material such as, for example, tetraethyl orthosilicate (TEOS), silicon dioxide (SiO₂), silicon carbon nitride (SiCN) and/or carbon-doped silicon oxide (SiCOH). The first bonding dielectric layer 24A can be formed by a deposition process such as, for example, CVD, PECVD, ALD, or physical vapor deposition (PVD). The first capacitor dielectric regions 26A are formed by forming openings in the first bonding dielectric layer 24A by lithography and etching. The openings that are formed in the first bonding dielectric layer 24A are then filled with a capacitor dielectric material by a deposition process such as, for example, CVD, PECVD or ALD, and thereafter a planarization process such as, for example, CMP, is used to remove any capacitor dielectric material that is formed outside the openings that are formed in the first bonding dielectric layer 24A. The capacitor dielectric material is composed of a compositionally different dielectric material than the dielectric material that provides the first bonding dielectric layer 24A. The capacitor dielectric material can include a capacitor dielectric such as, for example, silicon dioxide, a metal nitride (e.g., silicon nitride), or a material having a dielectric constant of greater than 4.0 such as, for example, TiO₂, Ta₂O₅, ZrO₂, including rare earth oxides such as Y₂O₃, La₂O₅, HfO₂, and their aluminates and silicates. In the present application, one of the first capacitor dielectric regions 26A is formed in direct contact with a surface of the uppermost first BEOL interconnect layer 14A that is located above a portion of the first wiring region 18A, and another of the first capacitor dielectric regions 26A is formed above, and in direct contact with, the first inductor 22A.

Referring now to FIG. 3B, there is illustrated the second exemplary semiconductor die shown in FIG. 2B after forming a second bonding dielectric layer 24B on the uppermost second BEOL interconnect dielectric layer 14B of the second BEOL structure 12B and forming second capacitor dielectric regions 26B in the second bonding dielectric layer 24B. Since the second bonding dielectric layer 24B is associated with the second (or bottom) semiconductor die, the second bonding dielectric layer 24B can also be referred to herein as a bottom bonding dielectric layer. The processing and materials mentioned above in forming the first bonding dielectric layer 24A and the first capacitor dielectric regions 26A are the same here for providing the second bonding dielectric layer 24B and the second capacitor dielectric regions 26B, respectively. In the present application, one of the second capacitor dielectric regions 26B is formed in direct contact with a surface of the uppermost second BEOL interconnect layer 14B that is located above a portion of the third wiring region 18B, and another of the second capacitor dielectric regions 26B is formed above, and in direct contact with, the second inductor 22B.

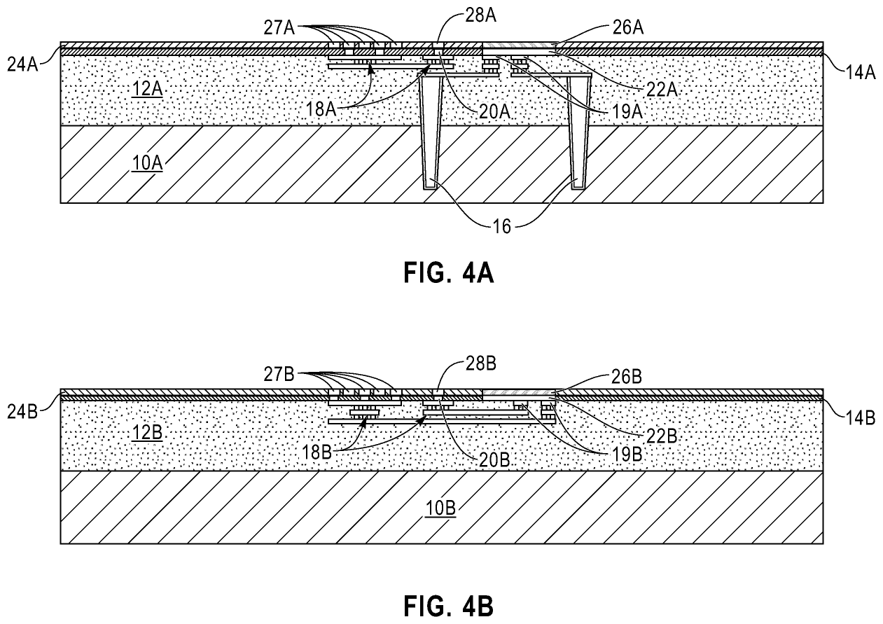

Referring now to FIG. 4A, there is illustrated the first exemplary semiconductor die shown in FIG. 3A after forming spaced apart first capacitor plates 27A in one of the first capacitor dielectric regions 26A. In the present application, the spaced apart first capacitor plates 27A represent elements of a first (or top) capacitor portion. The forming of the spaced apart first capacitor plates 27A includes forming openings within the first capacitor dielectric region 26A that is formed in direct contact with a surface of the uppermost first BEOL interconnect layer 14A. The number of openings can vary so long as at least one opening is formed. The openings can be formed by lithography and etching. Each opening is then filled with a capacitor plate metal-containing material utilizing a deposition process such as, for example, CVD, PECVD, ALD, sputtering or plating. A planarization process such as, for example, CMP follows the filling of the opening. The capacitor plate metal-containing material is composed of an electrically conductive material including, for example, one or the electrically conductive metals or metal alloys mentioned above, as well as Ti, Ta, TiN, or TaN.

The spaced apart first capacitor plates 27A can have various shapes including, for example, circular, rectangular, or square. The spaced apart first capacitor plates 27A and the remaining portions of the first capacitor dielectric region 24A that are adjacent to each of the first capacitors plates 27A provide a first (i.e., top) capacitor portion.

Also formed at the same time and utilizing the same process and material as the forming spaced apart first capacitor plates 27A is uppermost first metal via 28A. The uppermost first metal via 28A is formed in the first bonding dielectric layer 26A and is in connect with the first metal via 20A that was formed in the uppermost first BEOL interconnect dielectric layer 14A of the first BEOL structure 12A.

Referring now to FIG. 4B, there is illustrated the second exemplary semiconductor die shown in FIG. 3B after forming spaced apart second capacitor plates 27B in one of the second capacitor dielectric regions 26B. In the present application, the spaced apart second capacitor plates 27B represents elements of a second (or bottom) capacitor portion that will be subsequently bond with the first (or top) capacitor portion at the hybrid bonding interface to provide a single capacitor of the L-C circuit. The processing and material mentioned above in forming the spaced apart first capacitor plates 27A are the same here for providing the spaced apart second capacitor plates 27B. The spaced apart second capacitor plates 27B are formed in the second capacitor dielectric region 26B that is formed in direct contact with a surface of the uppermost second BEOL interconnect layer 14B.

The spaced apart second capacitor plates 27B can have various shapes including, for example, circular, rectangular, or square. The spaced apart second capacitor plates 27B and the remaining portion of the second capacitor dielectric region 26A that are adjacent to each of the second capacitors plates 27B provide a second (i.e., bottom) capacitor portion. The shape of the spaced apart first capacitor plates 27B is typically the same shape as that of the spaced apart second capacitor plates 27B.

In embodiments in which three or more capacitor plates are formed, the spaced apart first capacitor plates 27A and the spaced apart second capacitor plates 27B are components of an interdigital capacitor, i.e., a capacitor that has multi-finger periodic pattern of spaced apart capacitor plates. The interdigital capacitor allows for higher capacitance in a relatively smaller real estate at the HBI.

Also formed at the same time and utilizing the same process and material as the forming spaced apart second capacitor plates 27B is uppermost second metal via 28B. The uppermost second metal via 28B is formed in the second bonding dielectric layer 24B and is in connect with the second metal via 20B that was formed in the uppermost second BEOL interconnect dielectric layer 14B of the second BEOL structure 12B.

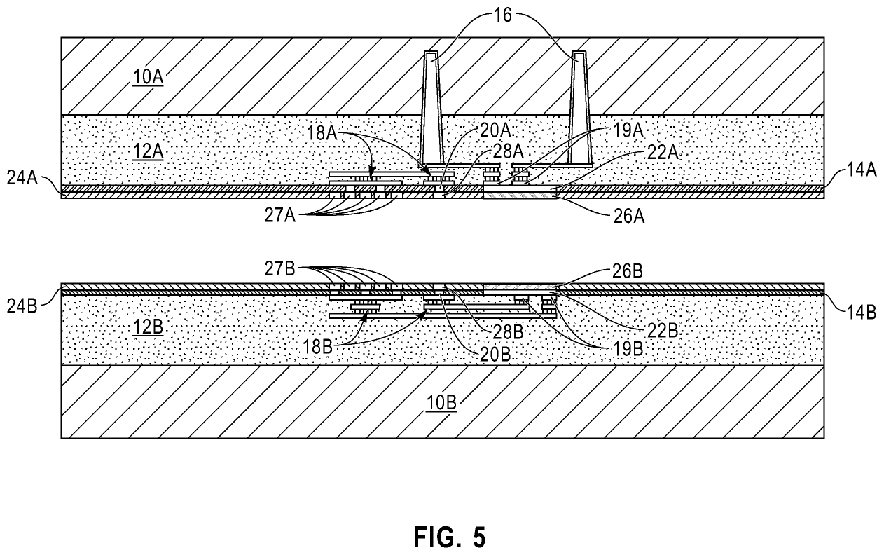

Referring now to FIG. 5, there is illustrated both the first and second exemplary semiconductor dies after flipping the first exemplary semiconductor die shown in FIG. 4A and aligning the flipped first exemplary semiconductor die over the second exemplary semiconductor die shown in FIG. 4B. In the present application, the first exemplary semiconductor die shown in FIG. 4A is flipped 180° such that the first combined FEOL/MOL structure 10A is now located on top of the first BEOL structure 12A. Flipping can be performed by hand or by utilizing a mechanical means such as, for example, a robot arm. The aligning includes positioning the flipped first exemplary semiconductor die over the second exemplary semiconductor die shown in FIG. 4B such that the spaced apart second capacitor plates 27B are aligned over the spaced apart first capacitor plates 27A and such that the second capacitor dielectric region 26B which was not processed to include spaced apart second capacitor plates 27B is aligned over the first capacitor dielectric region 26A which was not processed to include spaced apart first capacitor plates 27A.

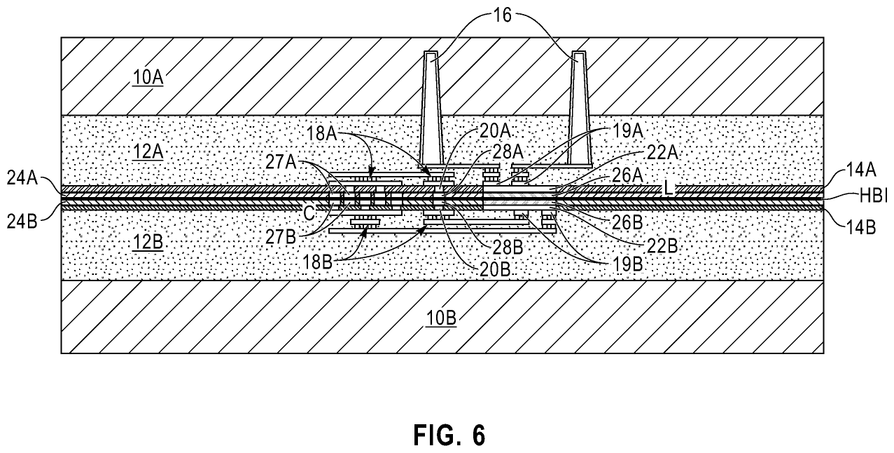

Referring now to FIG. 6, there is illustrated the flipped and aligned first exemplary semiconductor die and second exemplary semiconductor die shown in FIG. 5 after bringing the two exemplary semiconductor dies into intimate contact with each other and performing a bonding process to provide a structure having a hybrid bonded L-C circuit in accordance with the present application. The bringing the two exemplary semiconductor dies into intimate contact with each other can include the application of an external force which may or may not remain during the actual bonding process. The bonding process (which can also be referred to a hybrid bonding process) includes metal-to-metal bonding and dielectric-to-dielectric bonding. The bonding process includes heating the intimately contacted and aligned structures from room temperature (i.e., 20° C.-25° C.) up to 450° C.; temperatures greater than 450° C. can also be used in the present application. The bonding process is typically performed in an inert ambient such as, for example, He, Ar, Ne or mixtures thereof. After bonding, the temperature can be lowered back to room temperature. The bonding process can also include an activation process as described below.

Hybrid bonding refers to a 3D packing technique to connect semiconductor builds. Hybrid bonding forms connections of semiconductor structures through metal pads which are embedded in a dielectric layer at a bond interface on each semiconductor structure that is being bonded. The dielectric layer at bond interface include, but is not necessarily limited to, TEOS, SiO₂, SiCN, and/or SiCOH. The metal pads embedded in the dielectric surfaces most commonly include, but are not necessarily limited to, copper (Cu). As part of the hybrid bonding process, the aforementioned dielectric materials go through an activation process, including but not necessarily limited to, O₂/N₂ plasma activation followed by a de-ionized water rinsing. Such activation process creates surface dangling bonds through hydroxylation of dielectric surfaces. Hybrid bonding process itself includes alignment to control the overlay of metal pads and to ensure electrical continuity between semiconductor build undergoing hybrid bonding process, mating of dielectric/metal pad surfaces, annealing under a set pressure. The anneal process of the mated semiconductor builds ensures formation of covalent bonds between the dangling bonds across the dielectric surfaces of opposing semiconductor builds, as well as reflow (melting and joining) of the metal pads between the surfaces of opposing semiconductor builds to ensure electrical conductivity. The covalent bonds formed between the dielectric surfaces, and the joining of metal pads as a result of reflow process ensures that hybrid bonding interfaces joins two semiconductor builds and also ensures that there is electrical continuity between them. The dangling bonds and covalent bonding occurs in the present application.

Notably, and in the present application, the bonding process bonds (i.e., connects) the spaced apart second capacitor plates 27B to the spaced apart first capacitor plates 27A, bonds (i.e., connects) the second bonding dielectric layer 24B to the first bonding dielectric layer 24A, bonds the second capacitor dielectric region 26B which was not processed to include spaced apart second capacitor plates 27B to the first capacitor dielectric region 26A which was not processed to include spaced apart first capacitor plates 27A, and bonds (i.e., connects) the second capacitor dielectric region 26B which was processed to include spaced apart second capacitor plates 27B to the first capacitor dielectric region 26A which was processed to include spaced apart first capacitor plates 27A.

The bonding process forms a bonding interface, HBI, as shown in FIG. 6. Notably, the HBI is present between the bonded spaced apart second capacitor plates 27B and the spaced apart first capacitor plates 27A, the bonded second bonding dielectric layer 24B and the first bonding dielectric layer 24A, the bonded second capacitor dielectric region 26B which was not processed to include spaced apart second capacitor plates 27B and the first capacitor dielectric region 26A which was not processed to include spaced apart first capacitor plates 27A, and the bonded second capacitor dielectric region 26B which was processed to include spaced apart second capacitor plates 27B and the first capacitor dielectric region 26A which was processed to include spaced apart first capacitor plates 27A. The HBI thus contains metal-to-metal bonding and dielectric-to-dielectric bonding. The HBI also connects the various elements of the top portion and the bottom portion of the L-C circuit together. Notably, and as shown in FIG. 6 the first (top) capacitor portion is bonded to the second (bottom) capacitor portion forming elements of a single capacitor structure in the L-C circuit of the present application.

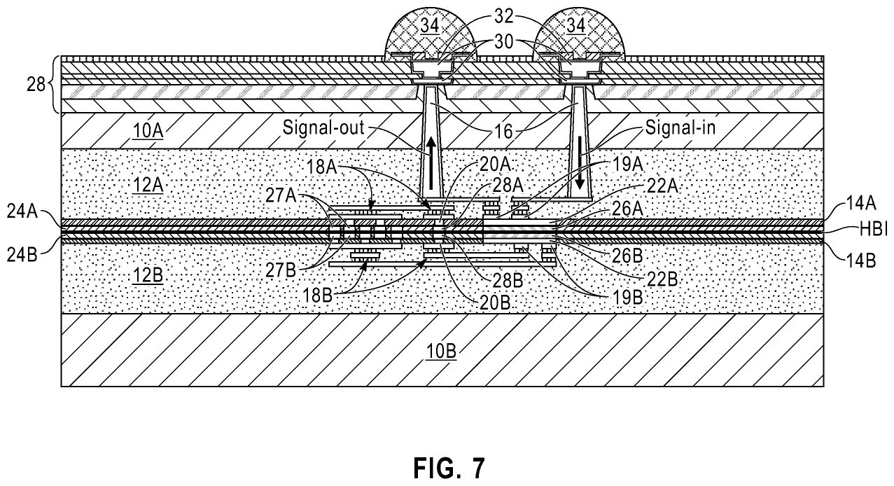

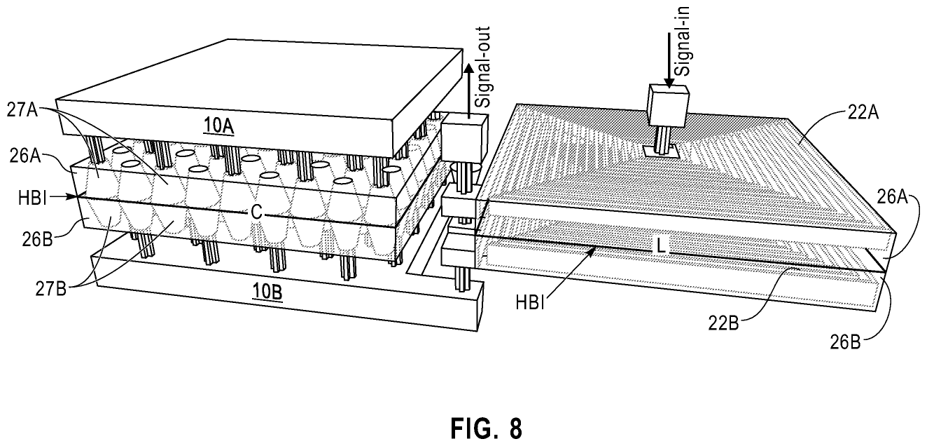

Referring now to FIG. 7, there is illustrated the hybrid bonded structure shown in FIG. 8 after further device processing. The further device processing includes first thinning the semiconducting material of the first semiconductor die by a planarization process including, for example, CMP and/or grinding, to physically expose a surface of each through via structure 16 that is embedded in the semiconducting material of the first combined FEOL/BEOL structure 10A. Various grindside dielectric layers 28 are then formed, followed by the formation of metal bond pads 30 and under bump metal structures 32, and thereafter solder bump 34 formation. The various grindside dielectric layers 28 include any dielectric material such as, for example, silicon dioxide, silicon nitride and/or silicon oxynitride. Each of the grindside dielectric layers 28 is formed utilizing a deposition process such as, for example, CVD, PECVD, PVD, or ALD. Metal bond pads 30 are formed utilizing a metallization process that includes lithography and etch an opening one or more of the dielectric materials that provide the grindside dielectric layers 28. The metallization process continues by forming an electrically conductive metal or metal alloy, as defined above, into the opening utilizing a deposition process (e.g., CVD, PECVD, ALD, sputtering or platting) into the opening. The metallization process can also include a planarization process such as CMP. The under bump metal structures 32 are then formed utilizing another metallization process, and thereafter solder bumps 34 are formed by deposition of a solder on the under bump metal structures 32.

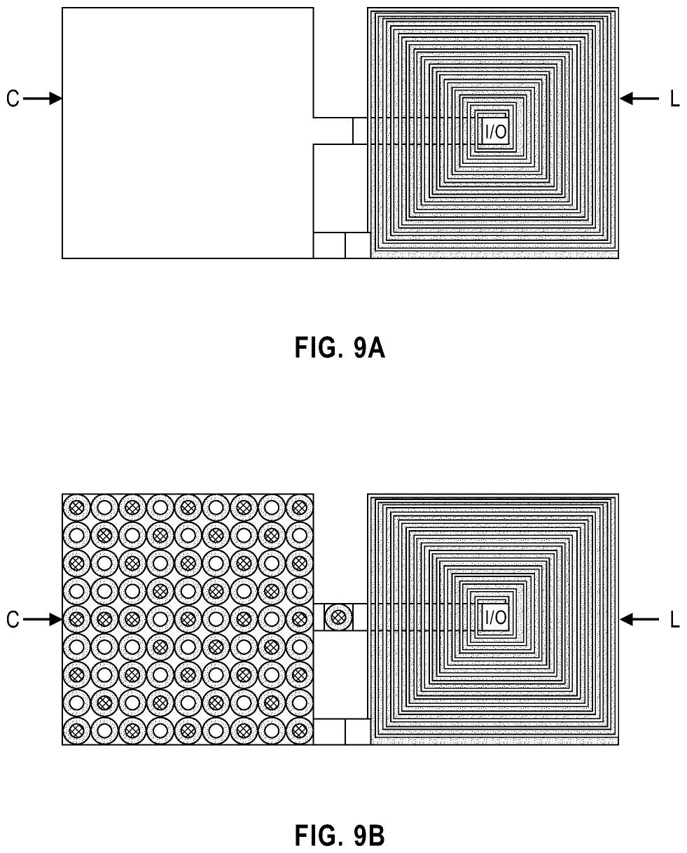

FIGS. 8, 9A and 9B illustrate various views of the hybrid bonded L-C circuit of the present application. Notably, FIG. 8 shows a 3D view of the hybrid bonded L-C circuit of the present application, FIG. 9A shows a top down view of the hybrid bonded L-C circuit of the present application, and FIG. 9B shows a cross sectional view of the hybrid bonded L-C circuit of the present application.

Referring now to FIGS. 10A-10E, there are illustrated various inductor shapes that can be employed in the hybrid bonded L-C circuit of the present application. These inductor shapes apply to the first inductor 22A and the second inductor 22B mentioned above. Notably, FIGS. 10A and 10B illustrate inductors having a rectangular shape, FIG. 10C illustrates an inductor having a square shape, FIG. 10D illustrates an inductor having a spiral shape, and FIG. 10E illustrates an inductor having a hexagonal shape. Other inductor shapes are possible and can be used as the shape of the first inductor 22A and the second inductor 22B mentioned above. In some embodiments, the shape of the first inductor 22A is the same as the shape of the second inductor 22B. In other embodiments, the shape of the first inductor 22A is different from the shape of the second inductor 22B. The different shapes allow for design and optimization of inductance (L) of the L-C circuit, depending on the nature of application.

In one aspect of the present application, a structure as illustrated in FIGS. 7, 8, 9A, and 9B is provided that includes bottom bonding dielectric layer (i.e., second bonding dielectric layer 24B) located on a surface of a bottom semiconductor die (including the second combined FEOL/MOL structure 10B and the second BEOL structure 12B). In the present application, the bottom bonding dielectric layer and the bottom semiconductor die have a bottom portion of an L-C circuit present therein. The structure further includes a top bonding dielectric layer (i.e., first bonding dielectric layer 24A) located on a surface of a top semiconductor die (including the first combined FEOL/MOL structure 10A and the first BEOL structure 12A) and in contact with the bottom bonding dielectric layer (i.e., second bonding dielectric layer 24B). In the present application, the top bonding dielectric layer and the top semiconductor die have a top portion of the L-C circuit present therein. In the structure, the top portion of the L-C circuit is connected to the bottom portion of the L-C circuit at a hybrid bonding interface HBI. The L-C circuit can be used as a monitoring device that can detect and transmit data related to at least one of temperature, strain and humidity at the hybrid bonding interface.

In embodiments of the present application, the hybrid bonding interface HBI is located between the top bonding dielectric layer (i.e., first bonding dielectric layer 24A) and the bottom bonding dielectric layer (i.e., second bonding dielectric layer 24B).

In embodiments of the present application, the hybrid bonding interface HBI that connects the bottom portion of the L-C circuit to the top portion of the L-C circuit includes a metal-to-metal bond and a dielectric-to-dielectric bond.

In embodiments of the present application, the top portion of the L-C circuit includes a top capacitor portion (including the spaced apart first metal plates 27A that are present in one of the first capacitor dielectric regions 26A) and a top inductor (i.e., first inductor 22A), and the bottom portion of the L-C circuit includes a bottom capacitor portion (including the spaced apart second metal plates 27B that are present in one of the second capacitor dielectric regions 26B) and a bottom inductor (i.e., second inductor 22B). In such embodiments, the top capacitor portion is connected to the bottom capacitor portion at the hybrid bonding interface, and the top inductor is connected to the bottom inductor at the hybrid bonding interface.

In embodiments of the present application, each of the top inductor (i.e., first inductor 22A) and the bottom inductor (i.e., second inductor 22B) is a planar structure.

In embodiments of the present application, each of the (i.e., first inductor 22A) and the bottom inductor (i.e., second inductor 22B) has a shape of a rectangle, a square, a spiral, or a hexagon. This allows for design and optimization of inductance (L) of the L-C circuit, depending on the nature of application.

In embodiments of the present application, each of the top capacitor portion and the bottom capacitor portion has a shape of a rectangle, a square, or a circle.

In embodiments of the present application, each of the top capacitor portion and the bottom capacitor portion is an interdigital capacitor having spaced apart capacitor plates that are separated from each other by a capacitor dielectric material. This allows for higher capacitance in a relatively smaller real estate at the HBI.

In embodiments of the present application, the (i.e., first inductor 22A) and the bottom inductor (i.e., second inductor 22B) are spaced apart by a capacitor dielectric material layer (i.e., first and second capacitor dielectric regions 26A and 26B) that is present at the hybrid bonding interface HBI. This allows for wireless transmission of the reliability data read by L-C circuit across the HBI and through the through via structure to I/O readout devices external to the semiconductor build.

In embodiments of the present application, the structure can further include a pair of through via structures (i.e., through via structures 16 mentioned above) present in the top semiconductor die and interconnected to the L-C circuit, wherein one of the through via structures of the pair of through via structures is configurated to allow a signal into the L-C circuit, and the other of the through via structures of the pair of through via structures is configurated to accept the signal that exists the L-C circuit.

In another aspect of the present application, a structure (as also illustrated in FIGS. 7, 8, 9A and 9B) is provided that includes a bottom bonding dielectric layer (i.e., second bonding dielectric layer 24B) located on a surface of a bottom semiconductor die (including the second combined FEOL/MOL level 10B and the second BEOL structure 12B). In this structure, the bottom bonding dielectric layer (i.e., second bonding dielectric layer 24B) has a bottom capacitor portion (including the spaced apart second metal plates 27B that are present in one of the second capacitor dielectric regions 26B) present therein and the bottom semiconductor die has a bottom inductor (i.e., second inductor 22B) present therein. This structure further includes a top bonding dielectric layer located (i.e., first bonding dielectric layer 24A) on a surface of a top semiconductor die (including the first combined FEOL/MOL level 10A and the first BEOL structure 12A) and in contact with the bottom bonding dielectric layer (i.e., second bonding dielectric layer 24B). In this structure, the top bonding dielectric layer (i.e., first bonding dielectric layer 24A) has a top capacitor portion (including the spaced apart first metal plates 27A that are present in one of the first capacitor dielectric regions 26A) present therein, and the top semiconductor die has a top inductor (first inductor 22A) present therein. This structure even further includes a hybrid bonding interface located between the bottom bonding dielectric layer and the top bonding dielectric layer at which the top inductor is connected, and the top capacitor portion is connected to the bottom capacitor portion. In this structure, the connected top capacitor portion and the bottom capacitor portion provide a capacitor. The capacitor and inductors of this embodiment can be used as a monitoring device that can detect and transmit data related to at least one of temperature, strain and humidity at the hybrid bonding interface.

In embodiments of the present application, the hybrid bonding interface HBI is located between the top bonding dielectric layer (i.e., first bonding dielectric layer 14A) and the bottom bonding dielectric layer (i.e., second bonding dielectric layer 14B).

In embodiments of the present application, the hybrid bonding interface HBI that connects the top inductor to the bottom inductor includes a dielectric-to-dielectric bond.

In embodiments of the present application, the hybrid bonding interface HBI that connects the top capacitor portion to the bottom capacitor portion includes a combination of a dielectric-to-dielectric bond and a metal-to-metal bond.

In embodiments of the present application, each of the top inductor and the bottom inductor has a shape of a rectangle, a square, a spiral, or a hexagon. The different shapes allow for design and optimization of inductance (L) of the L-C circuit, depending on the nature of application.

In embodiments of the present application, each of the top capacitor portion and the bottom capacitor portion has a shape of a rectangle, a square, or a circle.

In embodiments of the present application, the bottom capacitor portion and the top capacitor provide an interdigital capacitor having spaced apart capacitor plates that are separated from each other by a capacitor dielectric material layer.

In embodiments of the present application, the bottom capacitor portion includes a bottom interdigital capacitor portion and the top capacitor portion includes a top interdigital capacitor portion.

In embodiments of the present application, the structure can further include a bottom capacitor dielectric layer (i.e., second capacitor dielectric region 26B) located in the bottom bonding dielectric layer (i.e., second bonding dielectric layer 14B) and in direct physical contact with the bottom inductor (i.e., second inductor 22B), and a top capacitor dielectric layer (i.e., first capacitor dielectric region 26A) located in the top bonding dielectric layer (i.e., first and in direct physical contact with the top inductor, (i.e., first inductor 22A) in which the bottom capacitor dielectric layer contacts the top capacitor dielectric layer at the hybrid bonding interface HBI.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A structure comprising:
a bottom bonding dielectric layer located on a surface of a bottom semiconductor die, wherein the bottom bonding dielectric layer and the bottom semiconductor die have a bottom portion of an inductor-capacitor (l-C) circuit present therein; and
a top bonding dielectric layer located on a surface of a top semiconductor die and in contact with the bottom bonding dielectric layer, wherein the top bonding dielectric layer and the top semiconductor die have a top portion of the L-C circuit present therein, wherein the top portion of the L-C circuit is connected to the bottom portion of the L-C circuit at a hybrid bonding interface.

2. The structure of claim 1, wherein the hybrid bonding interface is located between the top bonding dielectric layer and the bottom bonding dielectric layer.

3. The structure of claim 1, wherein the hybrid bonding interface connecting the bottom portion of the L-C circuit to the top portion of the L-C circuit includes a metal-to-metal bond and a dielectric-to-dielectric bond.

4. The structure of claim 1, wherein the top portion of the L-C circuit comprises a top capacitor portion and a top inductor, and the bottom portion of the L-C circuit comprises a bottom capacitor portion and a bottom inductor, wherein the top capacitor portion is connected to the bottom capacitor portion at the hybrid bonding interface, and the top inductor is connected to the bottom inductor at the hybrid bonding interface.

5. The structure of claim 4, wherein each the top inductor and the bottom inductor is a planar structure.

6. The structure of claim 4, wherein each of the top inductor and the bottom inductor has a shape of a rectangle, a square, a spiral, or a hexagon.

7. The structure of claim 4, wherein each of the top capacitor portion and the bottom capacitor portion has a shape of a rectangle, a square, or a circle.

8. The structure of claim 4, wherein each of the top capacitor portion and the bottom capacitor portion is an interdigital capacitor having spaced apart capacitor plates that are separated from each other by a capacitor dielectric material layer.

9. The structure of claim 4, wherein the top inductor and the bottom inductor are spaced apart a capacitor dielectric material layer that is present at the hybrid bonding interface.

10. The structure of claim 1, further comprising a pair of through via structures present in the top semiconductor die and interconnected to the L-C circuit, wherein one of the through via structures of the pair of through via structures is configurated to allow a signal into the L-C circuit, and the other of the through via structures of the pair of through via structures is configurated to accept the signal that exists the L-C circuit.

11. A structure comprising:
a bottom bonding dielectric layer located on a surface of a bottom semiconductor die, wherein the bottom bonding dielectric layer has a bottom capacitor portion present therein and the bottom semiconductor die has a bottom inductor present therein;
a top bonding dielectric layer located on a surface of a top semiconductor die and in contact with the bottom bonding dielectric layer, wherein the top bonding dielectric layer has a top capacitor portion present therein and the top semiconductor die has a top inductor present therein; and
a hybrid bonding interface located between the bottom bonding dielectric layer and the top bonding dielectric layer at which the top inductor is connected to the bottom inductor, and the top capacitor portion is connected to the bottom capacitor portion.

12. The structure of claim 11, wherein the hybrid bonding interface is located between the top bonding dielectric layer and the bottom bonding dielectric layer.

13. The structure of claim 11, wherein the hybrid bonding interface that connects the top inductor to the bottom inductor includes a dielectric-to-dielectric bond.

14. The structure of claim 11, wherein the hybrid bonding interface that connects the top capacitor portion to the bottom capacitor portion includes a combination of a dielectric-to-dielectric bond and a metal-to-metal bond.

15. The structure of claim 11, wherein each of the top inductor and the bottom inductor has a shape of a rectangle, a square, a spiral, or a hexagon.

16. The structure of claim 11, wherein each of the top capacitor portion and the bottom capacitor portion has a shape of a rectangle, a square, or a circle.

17. The structure of claim 11, wherein the top capacitor portion and the bottom capacitor portion provide an interdigital capacitor having spaced apart capacitor plates that are separated from each other by a capacitor dielectric material layer.

18. The structure of claim 11, wherein the bottom capacitor portion comprises a bottom interdigital capacitor portion and the top capacitor portion comprises a top interdigital capacitor portion.

19. The structure of claim 11, further comprising a bottom capacitor dielectric layer located in the bottom bonding dielectric layer and in direct physical contact with the bottom inductor, and a top capacitor dielectric layer located in the top bonding dielectric layer and in direct physical contact with the top inductor, wherein the bottom capacitor dielectric layer contacts the top capacitor dielectric layer at the hybrid bonding interface.
